(19) United States
(12) Patent Application Publication
(10) Pub. No.: US 2006/0234411 A1
(43) Pub. Date: Oct. 19, 2006

(54) Method of manufacturing nitride semiconductor light emitting diode

(75) Inventors: Yung Ho Ryu, Seoul (KR); Pil Geun Kang, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/399,524

(22) Filed: Apr. 7, 2006

(30) Foreign Application Priority Data
Apr. 15, 2005 (KR) 10-2005-0031595

(51) Int. Cl. H01L 21/00

(52) U.S. Cl. 438/46; 257/E33.034

(57) ABSTRACT

The invention relates to a method of manufacturing a semiconductor light emitting diode. In the method, an n-type nitride semiconductor layer, an active layer and a p-type nitride semiconductor layer are formed sequentially on a substrate. Then, a nickel oxide (NiOₓ) film is directly deposited on the p-type semiconductor layer via reactive sputtering or reactive deposition in an oxidizing atmosphere. Also, a light transmissible conductive oxide layer is formed on the nickel oxide film.

### CLAIM OF PRIORITY

This application claims the benefit of Korean Patent Application No. 2005-0031595 filed on Apr. 15, 2005 in the Korean Intellectual Property Office, the disclosure of which is incorporated herein by reference.

### BACKGROUND OF THE INVENTION

1. Field of the Invention

The present invention relates to a method of manufacturing a nitride semiconductor light emitting diode. More particularly, the present invention relates to a novel method of manufacturing a nitride semiconductor light emitting diode which does not require heat processing to improve transmissibility of electrodes.

2. Description of the Related Art

In general, a group III-nitride semiconductor is made of a material having a relatively high energy band gap (e.g., about 3.4 eV for a GaN semiconductor) and well-utilized for optical devices to generate short wavelength light such as blue or green light. The nitride semiconductor is chiefly made of a material having a composition expressed by AlₓIn_{y}Ga_{(1-x-y)}N, where 0≦x≦1, 0≦y≦1 and 0≦x+y≦1.

However, the nitride semiconductor hardly establishes an ohmic contact with electrodes due to a relatively high energy band gap thereof. Especially, a larger energy band gap of a p-type nitride semiconductor layer results in higher contact resistance in an area contacting a p-electrode. This consequently increases operating voltage of a diode and a light emitting amount.

Therefore, the nitride semiconductor light emitting diode requires the ohmic contact to be enhanced in forming the p-electrode. However, in a structure other than a flip-chip structure, light exits mostly through a p-electrode area. As a result, improving the ohmic contact described above entails technical limitations since light transmissibility needs to be also ensured.

A conventional representative ohimic contact technique is disclosed in U.S. Pat. No. 5,563,422 (“Gallium Nitride-Based III-V Group Compound Semiconductor Device And Method of Producing the Same” assigned to Nichia Chemical Industry Ltd.) which relates to a transparent electrode layer using a double layer of Ni/Au. FIG. 1 illustrates one embodiment of the light emitting diode according to the aforesaid U.S. patent.

As shown in FIG. 1, a conventional nitride light emitting diode 10 includes a buffer layer 12 formed on a sapphire substrate 11, a GaN nitride layer 13 formed on the buffer layer 12, a GaN/InGaN active layer of a multiple well structure 14 formed on the GaN nitride layer 13 and a p-type GaN nitride layer 15 formed on the GaN/InGaN layer of the multiple well structure 14. The p-type GaN nitride layer 15 and the GaN/InGaN active layer 14 are partially removed, thereby exposing a partial surface of the n-type GaN nitride layer 13.

An n-electrode 19a is formed on the n-type GaN nitride layer 13, and a transparent electrode 17 made of Ni/Au is formed on the p-type GaN nitride layer 14 to form an ohmic contact. Then a p-bonding electrode 19b is formed on the transparent electrode 17. Also, the transparent electrode 17 is formed by depositing the double layer of Ni/Au, necessarily followed by heat processing. Ni serves to improve a contact resistance along with Au, and becomes a light transmissible nickel oxide (NiOₓ) in the following heat processing.

Another conventional method employs a conductive oxide layer such as indium tin oxide (ITO) purported to have a light transmissibility of about 90% or more. But, due to the ITO's weak bonding force for a GaN crystal and considerable work function differences between a p-type GaN layer (about 7.5 eV) and the ITO (about 4.7 to 5.2 eV), an ohmic contact is not made in case of directly depositing the ITO on the p-type GaN layer.

In an attempt to deposit ITO, the p-type GaN layer 15 is doped with a material having a low work function such as Zn, or with C at a high concentration to reduce the work function of the p-GaN layer. However, the doped Zn or C is highly mobile so that it may be diffused to a lower part of the p-type GaN layer 15 in case of a long-term use of the light emitting diode. Disadvantageously, this undermines credibility of the light emitting diode.

In the art, there have been demands for a simpler process to form a superior ohmic contact structure contacting the p-type nitride layer.

### SUMMARY OF THE INVENTION

The present invention has been made to solve the foregoing problems of the prior art and it is therefore an object of the present invention to provide a novel method of manufacturing a nitride semiconductor light emitting diode capable of establishing a superior ohmic contact without heat processing by directly depositing a nickel oxide to a thickness that ensures light transmissibility and combining the same with a light transmissible conductive oxide layer.

According to an aspect of the invention for realizing the object, there is provided a method for manufacturing a nitride semiconductor light emitting diode comprising steps of:
forming an n-type nitride semiconductor layer, an active layer and a p-type nitride semiconductor layer sequentially on a substrate;
directly depositing a nickel oxide (NiOₓ) film on the p-type semiconductor layer via reactive sputtering or reactive deposition in an oxidizing atmosphere; and
forming a light transmissible conductive oxide layer on the nickel oxide film.

Preferably, the nickel oxide film has a thickness of about 10 Å to about 20 Å. In case of the thickness less than about 10 Å, a sufficient ohmic contact cannot be attained. Also, the thickness exceeding about 20 Å causes light loss to increases proportional to the thickness of the nickel oxide film, thereby hardly ensuring high brightness.

Preferably, the oxidizing atmosphere is an O₂ atmosphere or an H₂O atmosphere.

According to the invention, the light transmissible conductive oxide layer comprises one selected from a group consisting of ITO, ZnO and MgO. Indium tin oxide (ITO) is considered preferable. In case where the light transmissible conductive oxide layer is made of ITO, preferably, the ITO layer has a thickness of about 800 Å to about 6000 Å.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a conventional nitride semiconductor light emitting device; and

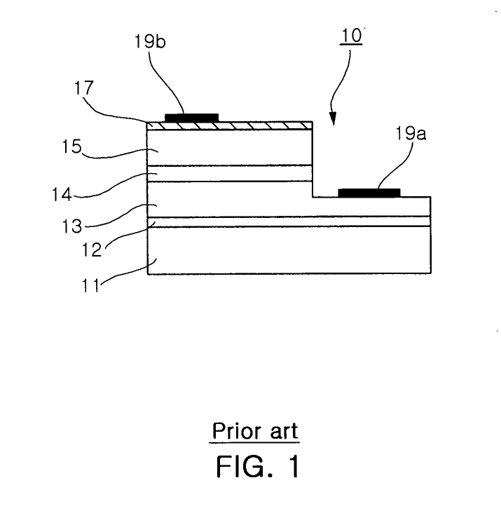

FIGS. 2a to 2d are sectional views illustrating a method of manufacturing a nitride semiconductor light emitting diode according to the invention.

### DETAILED DESCRIPTION OF THE PREFERRED EMBODIMENT

Preferred embodiments of the present invention will now be described in detail with reference to the accompanying drawings.

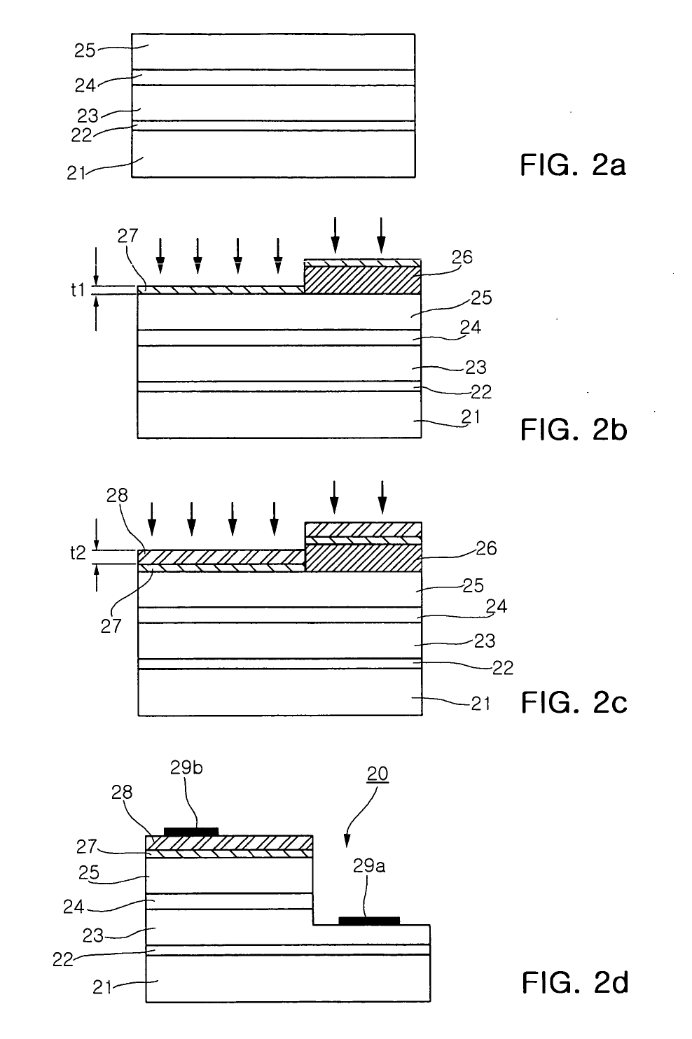

FIGS. 2a to 2d are sectional views illustrating a method of manufacturing a nitride semiconductor light emitting diode according to the invention.

The manufacturing method according to the invention, as shown in FIG. 2a, starts with forming an n-type nitride semiconductor layer 23, an active layer 24 and a p-type nitride semiconductor layer 25 sequentially on a substrate 21. The substrate 21 may be a sapphire substrate, a heterogeneous substrate made of e.g, SiC, or a homogenous substrate made of GaN. The substrate 21 may additionally include a buffer layer 22 made of e.g, AlN, GaN, or AlGaN grown at a low temperature. The nitride semiconductor layer (22,23,24 and 25) may be grown by metal-organic chemical vapor deposition (MOCVD), hydride vapor physe epitaxy (HVPE), and molecular beam epitaxy (MBE).

Thereafter, a photoresist is applied on the p-type nitride semiconductor layer 25 and then selectively removed to form a photoresist pattern 26 that exposes an ohmic contact forming area of the p-type nitride semiconductor layer 25. The mesa-etched ohmic contact forming area may correspond to a surface area of the remaining p-type nitride semiconductor layer 25. After the forming of the photoresist pattern 26, a nickel oxide (NiOₓ) film 27 is directly deposited on the exposed p-type nitride semiconductor layer 25. Herein, direct deposition of the nickel oxide film 27 means forming the nickel oxide itself by sputtering or deposition without heat processing.

The nickel oxide film 27 may be directly formed on the exposed area of the p-type nitride semiconductor layer 25 via reactive sputtering or reactive deposition in an oxidizing atmosphere. The oxidizing atmosphere is an O₂ atmosphere or an H₂O atmosphere.

Preferably, the nickel oxide film 27 has a thickness t1 of about 10 to 20 Å. In case of the thickness t1 less than 10 Å, a sufficient ohmic contact cannot be attained. But the thickness exceeding about 20 Å causes light loss to increases proportional to the thickness of the nickel oxide film 27, thus hardly ensuring high brightness. Consequently, adjustment in the thickness allows sufficient transmissibility and minimizes problems resulting from a relatively high voltage. Within the preferable thickness range, advantageously, to improve conductivity, additional conductive material does not need to be solved into the nickel oxide.

Thereafter, as shown in FIG. 2c, a light transmissible conductive oxide layer 28 is formed on the nickel oxide film 27. The light transmissible conductive oxide layer 28 is selected from a group consisting of ITO, ZnO and MgO. The light transmissible conductive oxide layer 28 is formed via reactive deposition or sputtering in a similar manner to the nickel oxide film 27, thus allowing a continuous process.

Especially, in the invention, the nickel oxide film 27 is directly deposited in the preceding process, thus not requiring separate heat processing to produce the nickel oxide after depositing nickel (Ni) as in the conventional method. Therefore, the method of manufacturing a nitride semiconductor light emitting diode according to the invention allows continuous deposition for LED layers including an ITO layer in a single chamber.

The light transmissible conductive oxide layer 28 exhibits a high transmissibility of 90% or more, and a relatively higher resistance than a general metal, thereby ensuring current spreading effect. As a result, high brightness properties can be guaranteed based on the ohmic contact of the nickel oxide film 27.

In case where ITO is used as the light transmissible conductive oxide layer 28, preferably, the ITO layer 28 has a thickness t2 of at least 800 Å. This is because the thickness of less than 800 Å does not ensure current spreading effect sufficiently. The thickness exceeding 6000 Å disadvantageously increases operating voltage.

Then, after lifting off of a photoresist pattern, a mesa-etching is performed via additional mask process to produce the n-type nitride layer area for forming electrodes. Thereafter, a p-bonding electrode is formed on the ITO electrode and an n-bonding electrode is formed on the exposed n-type nitride layer area. The p-bonding electrode is made of Au or an alloy thereof. The n-electrode is formed of a single layer or a multiple layer selected from a group consisting of Ti, Cr, Al, Cu and Au.

As set forth above, according to the invention, to form a superior ohmic contact, a nickel oxide is directly deposited to an adequate thickness that can ensure sufficient light transmissibility and reduce electrical loss, and is combined with a light transmissible conductive oxide layer having current spread effect. Thereby, the invention allows manufacture of a nitride light emitting device having a superior ohmic contact structure and high brightness in a simpler process.

While the present invention has been shown and described in connection with the preferred embodiments, it will be apparent to those skilled in the art that modifications and variations can be made without departing from the spirit and scope of the invention as defined by the appended claims.

What is claimed is:

1. A method for manufacturing a nitride semiconductor light emitting diode comprising steps of:
forming an n-type nitride semiconductor layer, an active layer and a p-type nitride semiconductor layer sequentially on a substrate;
directly depositing a nickel oxide (NiOₓ) film on the p-type semiconductor layer via reactive sputtering or reactive deposition in an oxidizing atmosphere; and
forming a light transmissible conductive oxide layer on the nickel oxide film.

2. The method according to claim 1, the nickel oxide film has a thickness of about 10 Å to about 20 Å.

3. The method according to claim 1, wherein the oxidizing atmosphere is an O₂ atmosphere or an H₂O atmosphere.

4. The method according to claim 1, wherein the light transmissible conductive oxide layer comprises one selected from a group consisting of ITO, ZnO and MgO.

5. The method according to claim 1, wherein the light transmissible conductive oxide layer comprises an indium tin oxide layer, wherein the indium tin oxide layer has a thickness of about 800 Å to about 6000 Å.
